(19) United States
(12) Patent Application Publication
(10) Pub. No.: US 2026/0280141 A1
(43) Pub. Date: Sep. 17, 2026

(54) METHOD AND SYSTEM FOR ANTENNA STRUCTURE OPTIMIZATION DESIGN

(71) Applicant: 38TH RESEARCH INSTITUTE, CHINA ELECTRONICS TECHNOLOGY GROUP CORPORATION, Hefei (CN)

(72) Inventors: Hongqi ZHANG, Hefei (CN); Wenjun SHENG, Hefei (CN)

(21) Appl. No.: 19/461,707

(22) Filed: Jan. 27, 2026

Related U.S. Application Data
(63) Continuation of application No. PCT/CN2025/099461, filed on Jun. 6, 2025.

(30) Foreign Application Priority Data
Mar. 11, 2025 (CN) 202510279201.8

(51) Int. Cl. H01Q 21/00; G06F 30/36; H04B 17/391

(52) U.S. Cl. CPC H01Q 21/0087; G06F 30/36; H04B 17/3912

(57) ABSTRACT

A method for antenna structure optimization design includes the following steps. A structural model is determined based on installation requirements of a composite phased-array antenna. A design indicator and a reliability requirement are determined with structural strength limit and electrical performance design limit as design constraints. A design parameter is extracted, and a noise parameter is determined. A relationship between the design parameter, the noise parameter, an optimization object and the design constraint, and a surrogate model are established. A reliability-based optimization design is performed on the composite phased-array antenna to determine a target solution meeting the design constraint and characterizing the corresponding design parameter. A system for antenna structure optimization design is also provided.

### CROSS-REFERENCE TO RELATED APPLICATIONS

This application is a continuation of International Patent Application No. PCT/CN2025/099461, filed on Jun. 6, 2025, which claims the benefit of priority from Chinese Patent Application No. 202510279201.8, filed on Mar. 11, 2025. The content of the aforementioned application, including any intervening amendments made thereto, is incorporated herein by reference in its entirety.

### TECHNICAL FIELD

This application relates to antenna digital design technology, and more particularly to a method and system for antenna structure optimization design.

### BACKGROUND

A phased-array antenna generally has functional units of an antenna unit array, a processing unit, a power supply unit and a transceiver module. These functional units are arranged on an antenna structure, which serves as a main load-bearing structure, consisting of an antenna array mounting plate and an antenna truss structure.

In the existing technologies, the antenna structure is processed from relatively light metal materials such as aluminum alloy. Given the increasingly strict weight requirements in the aerospace field, a composite material has gradually replaced the aluminum alloy due to its advantages of superior stiffness and light weight. The composite material is significantly different from traditional elemental and uniform metal materials. The structural dimensions and mechanical properties of the composite material are highly sensitive to the processing environment and manufacturing process, presenting typical characteristics of an anisotropy and a high dispersion in the mechanical properties.

The conventional design method based on safety factors fails to consider uncertainties in the structural dimensions and mechanical properties of the composite material. It often leads to excessive redundancy in the stiffness and strength of a composite phased-array antenna, resulting in a larger weight margin. As a consequence, the composite phased-array antenna structure lacks the advantage of light weight, and is difficult to be adopted in the aerospace field. Therefore, there is an urgent need to propose a method and system for antenna structure optimization design to consider the uncertainties.

### SUMMARY

In view of the above disadvantages, the present disclosure provides a method and system for antenna structure optimization design to address the problem that a structural lightweight design of a composite phased-array antenna in the aerospace field poses a difficulty to balance reliability, stiffness, strength and lightweight.

In order to achieve the above object, the following technical solutions are adopted herein.

In a first aspect, a method for antenna structure optimization design, comprising:
(S1) according to installation requirements, determining a structural model corresponding to a composite phased-array antenna;
(S2) setting a structural strength limit and an electrical performance design limit of the composite phased-array antenna as a design constraint; and determining a design indicator of the design constraint and a reliability requirement thereof, so as to obtain a limit state space based on the design constraint;
(S3) extracting design parameters of the composite phased-array antenna based on the structural model, wherein the design parameters comprise a deterministic design parameter and a random design parameter;
(S4) determining a noise parameter of the composite phased-array antenna that follows a random probability distribution, wherein the noise parameter is related to the design constraint, and comprises a prepreg ply orientation, a single-ply prepreg thickness and variations of antenna unit mounting points on an antenna unit mounting plate;
(S5) establishing a relationship between the design parameters and an optimization object, and the design constraint based on the structural model; establishing a relationship between the noise parameter and the optimization object, and the design constraint based on the structural model; and establishing a surrogate model based on the two relationships; wherein the optimization object is to minimize a structural weight of the composite phased-array antenna;
(S6) based on the noise parameter and the optimization object, establishing a reliability optimization model with the design parameter as a variable and the limit state space as an optimization constraint; and
(S7) performing reliability-based optimization design on a structure of the composite phased-array antenna to determine a target solution that satisfies the design constraint and characterizes the design parameter.

In a second aspect, a system for antenna structure optimization design, comprising:
a first determination module;
a second determination module;
an extraction module;
a third determination module;
a first establishment module;
a second establishment module; and
an optimization design module;
wherein the first determination module is configured, according to installation requirements, to determine a structure model corresponding to a composite phased-array antenna;
the second determination module is configured to set a structural strength limit and an electrical performance design limit of the composite phased-array antenna as a design constraint, and to determine a design indicator of the design constraint and a reliability requirement thereof, so as to obtain a limit state space based on the design constraint;
the extraction module is configured to extract design parameters of the composite phased-array antenna based on a structural model, wherein the design parameters comprise a deterministic design parameter and a random design parameter;
the third determination module is configured to determine a noise parameter of the composite phased-array antenna that follows a random probability distribution, wherein the noise parameter is related to the design constraint, and comprises a prepreg ply orientation, a single-ply prepreg thickness and variations of antenna unit mounting points on an antenna unit mounting plate;
the first establishment module is configured to establish a relationship between the design parameters and an optimization object, and the design constraint based on the structural model, to establish a relationship between the noise parameter and the optimization object, and the design constraint based on the structural model, and to establish a surrogate model based on the two relationships, wherein the optimization object is to minimize a structural weight of the composite phased-array antenna;
the second establishment module is configured, based on the noise parameter and the optimization object, to establish a reliability optimization model with the design parameter as a variable and the limit state space as an optimization constraint; and
the optimization design module is configured to perform reliability-based optimization design on a structure of the composite phased-array antenna to determine a target solution that satisfies the design constraint and characterizes the design parameter.

In a third aspect, an electronic device, comprising:
a processor;
a memory; and
a program stored on the memory and executed by the processor;
wherein the program is configured, when executed by the processor, to cause the processor to implement the aforementioned method.

Compared to the prior art, the method and the system for antenna structure optimization design provided herein have the following beneficial effects.

In the design process, this application considers various factors, such as the deterministic design parameter, the random design parameter and the uncertainties in the structural dimensions and mechanical properties of the composite phased-array antenna. Moreover, the design constraint is introduced into the design process, comprising the structural strength limit and the electrical performance design limit. By incorporating the various loads endured by the antenna structure under an in-service status, the stiffness and strength indicators of the antenna structure are analyzed.

Based on the stiffness, strength and electrical performance of the antenna structure under the in-service status, this application considers the uncertainties in the structural dimensions and mechanical properties. Rapid weight optimization of the antenna structure is performed with the structural weight of the composite phased-array antenna as the optimization object under the condition of ensuring the confidence in the structural performance of the antenna.

Compared to the conventional design method based on safety factors, this application enables a more thorough lightweight design for the phased-array antenna structure, while ensuring a high reliability that the stiffness, strength and electrical performance indicators satisfy the requirements, thereby significantly shortening the design iteration cycle for the composite phased-array antenna and substantially reducing development costs.

### BRIEF DESCRIPTION OF THE DRAWINGS

In order to illustrate the technical solutions in the prior art or in the embodiments of the present disclosure more clearly, the accompanying drawings needed in the description of the prior art or the embodiments of the present disclosure will be briefly described below. Obviously, presented in the accompanying drawings are merely some embodiments of the disclosure, and other drawings can also be obtained by those skilled in the art based on these accompanying drawings without paying creative effort.

FIG. 1 is a flow chart of a method for antenna structure optimization design according to an embodiment of the present disclosure;

FIG. 2 is a flow chart of step (S150) in FIG. 1;

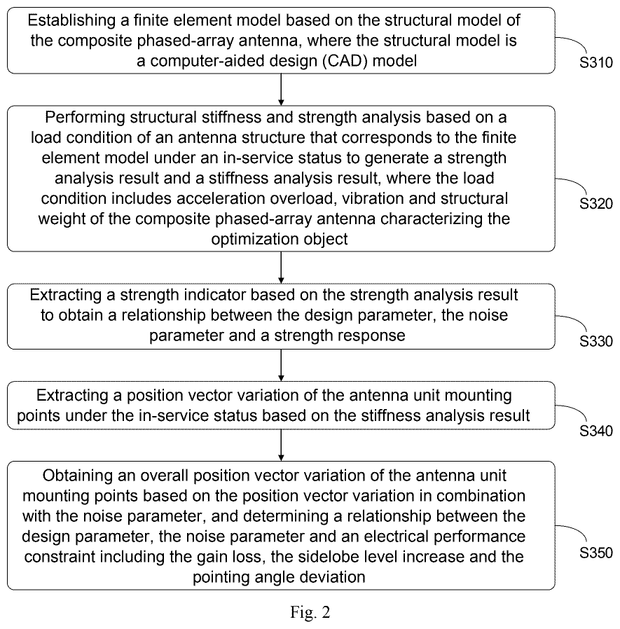

FIG. 3 is another flow chart of the step (S150) in FIG. 1;

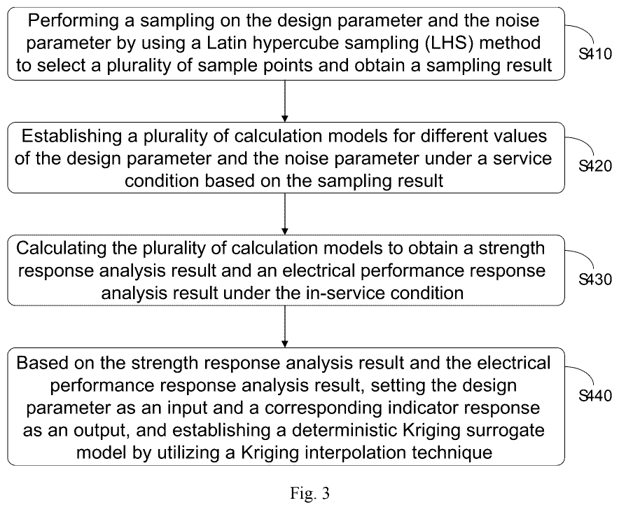

FIG. 4 structurally shows a composite phased-array antenna according to an embodiment of the present disclosure;

FIG. 5 structurally shows a system for antenna structure optimization design according to an embodiment of the present disclosure; and

FIG. 6 structurally shows an electronic device according to an embodiment of the present disclosure.

In the figures: 101—antenna unit mounting plate; 102—antenna unit mounting hole; and 103—truss structure.

### DETAILED DESCRIPTION OF EMBODIMENTS

To make the objectives, technical solutions and advantages of the embodiments of the present disclosure clearer, the technical solutions of the embodiments in the present disclosure will be described clearly and completely. Obviously, described below are merely some embodiments of the present disclosure, instead of all embodiments of the disclosure. Based on the embodiments in the present disclosure, all other embodiments obtained by those of ordinary skill in the art without paying creative labor shall fall within the scope of the present disclosure.

It should be noted that, the terms “first” and “second” are only for descriptive purposes to differ an entity or operation from another entity or operation, and should not be understood as indicating or implying the practical relationship or the sequence of the entities or operations involved. Furthermore, the terms “comprise”, “include”, and any variations thereof are intended to cover the non-exclusive inclusion, such that a process, method, article, or apparatus including a series of elements not only includes those elements but also includes other elements not explicitly listed, or elements inherent to such as process, method, article, or apparatus. In the absence of further limitations, an element defined by the phrase “comprising a . . . ” does not exclude the presence of additional identical elements in the process, method, article, or apparatus that includes the specified element.

The embodiments of the present disclosure provide a method and system for antenna structure optimization design to address the problem that a structural lightweight design of a composite phased-array antenna in the aerospace field poses a difficulty to balance reliability, stiffness, strength and lightweight.

To address the above technical problem, the technical solutions in the embodiments of the present disclosure are proposed herein.

A phased-array antenna generally has functional units of an antenna unit array, a processing unit, a power supply unit and a transceiver module. These functional units are arranged on an antenna structure, which serves as a main load-bearing structure, consisting of an antenna array mounting plate and an antenna truss structure.

In the existing technologies, the antenna structure is processed from relatively light metal materials such as aluminum alloy. Given the increasingly strict weight requirements in the aerospace field, a composite material has gradually replaced the aluminum alloy due to its advantages of superior stiffness and light weight. The composite material is significantly different from traditional elemental and uniform metal materials. The structural dimensions and mechanical properties of the composite material are highly sensitive to the processing environment and manufacturing process, presenting typical characteristics of an anisotropy and a high dispersion in the mechanical properties.

The conventional design method based on safety factors fails to consider uncertainties in the structural dimensions and mechanical properties of the composite material. It often leads to excessive redundancy in stiffness and strength of a composite phased-array antenna, resulting in a larger weight margin. As a consequence, the composite phased-array antenna structure lacks the advantage of light weight, and is difficult to be adopted in the aerospace field. Therefore, there is an urgent need to propose a method and system for antenna structure optimization design to consider the uncertainties.

The above technical solutions are detailly described below with reference to the accompanying figures of the description, and the specific embodiments for better understanding.

A method for antenna structure optimization design according to an embodiment of the present disclosure is illustrated below.

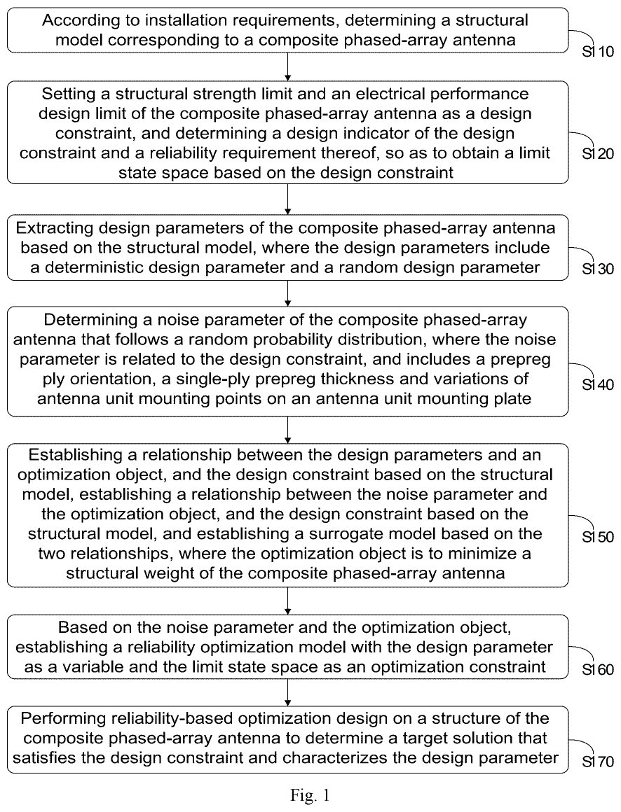

A flow chart of the method for antenna structure optimization design according to an embodiment of the present disclosure is shown in FIG. 1. This method includes the following steps (S110-S170).

(S110) According to installation requirements, a structural model corresponding to a composite phased-array antenna, is determined.

(S120) A structural strength limit and an electrical performance design limit of the composite phased-array antenna are set as a design constraint, and a design indicator of the design constraint and a reliability requirement thereof are determined, so as to obtain a limit state space based on the design constraint.

(S130) Design parameters of the composite phased-array antenna are extracted based on the structural model, where the design parameters include a deterministic design parameter and a random design parameter.

(S140) A noise parameter of the composite phased-array antenna that follows a random probability distribution is determined, where the noise parameter is related to the design constraint, and includes a prepreg ply orientation, a single-ply prepreg thickness and variations of antenna unit mounting points on an antenna unit mounting plate. The noise parameter is an unoptimizable parameter that follows the random probability distribution, where the random probability distribution is a normal distribution or a Poisson distribution.

(S150) A relationship between the design parameters and an optimization object, and the design constraint is established based on the structural model. A relationship between the noise parameter and an optimization object, and the design constraint is established based on the structural model. A surrogate model is established based on the two relationships. The optimization object is to minimize a structural weight of the composite phased-array antenna.

(S160) Based on the noise parameter and the optimization object, a reliability optimization model is established with the design parameter as a variable and the limit state space as an optimization constraint.

(S170) Reliability-based optimization design is performed on a structure of the composite phased-array antenna to determine a target solution that satisfies the design constraint and characterizes the design parameter.

The embodiments of the present disclosure provide a specific implementation method as described above, which relates to the method for antenna structure optimization design.

It should be understood that, in the design process, this application considers various factors, such as the deterministic design parameter, the random design parameter and the uncertainties in the structural dimensions and mechanical properties of the composite phased-array antenna. Moreover, the design constraint is introduced into the design process, including the structural strength limit and the electrical performance design limit. By incorporating the various loads endured by the antenna structure under an in-service status, the stiffness and strength indicators of the antenna structure are analyzed.

In view of this, based on the stiffness, strength, and electrical performance of the antenna structure under the in-service status, this application considers the uncertainties in the structural dimensions and mechanical properties. Rapid weight optimization of the antenna structure is performed with the structural weight of the composite phased-array antenna as the optimization object under the condition of ensuring the confidence in the structural performance of the antenna.

Compared to the conventional design method based on safety factors, this application enables a more thorough lightweight design for the phased-array antenna structure, while ensuring a high reliability that the stiffness, strength and electrical performance indicators satisfy the requirements, thereby significantly shortening the design iteration cycle for the composite phased-array antenna and substantially reducing development costs.

It should be noted that the variations of the antenna unit mounting points are produced by a manufacturing tolerance. The noise parameter is the random design parameter that cannot be optimized or is difficult to be optimized, which has an influence on the design constraint of the composite phased-array antenna. A prepreg ply orientation of carbon fiber a, a single-ply prepreg thickness of carbon fiber fabric T and a manufacturing tolerance of the antenna unit mounting points Arm are set as the noise parameter.

In some embodiments, the prepreg ply orientation and the single-ply prepreg thickness are correlated with the stiffness and strength of the composite phased-array antenna. The variations of the antenna unit mounting points are correlated with the electrical performance of the composite phased-array antenna.

It should be noted that, the prepreg ply orientation and the single-ply prepreg thickness have influences on the stiffness and strength of the composite phased-array antenna. The variations of the antenna unit mounting points have a direct influence on the electrical performance of the composite phased-array antenna. An average and a variance of the prepreg ply orientation, the single-ply prepreg thickness and the variations of the antenna unit mounting points are respectively determined based on experience and experiment data, so as to calculate the design constraint and the uncertainties of the composite phased-array antenna, respectively.

In some embodiments, step (S110) is performed through the following steps.

(S210) The installation requirements of the composite phased-array antenna are obtained, where the installation requirements include a first mounting interface and an external envelope for each of a plurality of standalone modules, and each of the plurality of standalone modules includes the antenna unit array, a power supply unit and a transceiver unit.

(S220) A structural design information of the composite phased-array antenna is determined based on the installation requirements, where the structural design information includes external dimension, composite structural design, position of the metal embedded part and a second mounting interface.

(S230) The structural model of the composite phased-array antenna is determined based on the structural design information.

It should be understood that a phased-array antenna refers to an antenna configured for changing a shape of a radiation pattern by controlling a feed phase of a radiation unit in an array antenna. A phase is controlled to change an orientation of a maximum for the radiation pattern of the array antenna, so as to enable a beam scanning. The composite phased-array antenna is provided with the plurality of standalone modules. After determining the installation requirements, a deepening design is correspondingly performed to obtain the structural model.

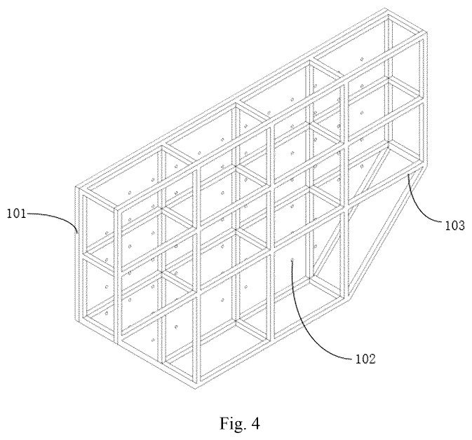

In some embodiments, referring to FIG. 4, the structure of the composite phased-array antenna includes the antenna unit mounting plate 101 and a truss structure 103. The antenna unit mounting plate 101 is provided with a plurality of antenna unit mounting holes 102 arranged in an array distribution. The plurality of antenna unit mounting holes 102 are configured to mount an antenna unit array. The truss structure 103 is formed by joining a plurality of hollow carbon fiber square tubes, and a metal embedded part is provided at a joint between two adjacent tubes of the plurality of hollow carbon fiber square tubes.

In some embodiments, the antenna unit mounting plate 101 is configured as a sandwich structure, including two composite skins and a middle layer. The two composite skins of the antenna unit mounting plate 101 are each made of a carbon fiber fabric, which is formed by compressing a plurality of carbon fiber fabric prepreg layers. The middle layer of the antenna unit mounting plate 101 is made of a foam material and is mounted on the truss structure 103 through a rivet.

In some embodiments, the design indicator of the structural strength limit includes a maximum von Mises stress, a maximum shear force of a composite core material, a maximum strain of a composite skin, a Tsai-Wu coefficient and a buckling eigenvalue corresponding to rod or panel buckling failure. The electrical performance design limit is configured to characterize an overall electrical performance of the composite phased-array antenna. The design indicator corresponding to the electrical performance design limit includes a radiation pattern, a pointing angle deviation, a gain loss and a sidelobe level increase.

It should be understood that, in the design process, this application considers the structural strength limit and the electrical performance design limit. Regarding the structural strength limit, on one hand, the metal embedded part in the antenna structure generally has a plastic failure, such that the maximum von Mises stress σ is set as a structural strength limit of the metal embedded part; on the other hand, the composite material in the antenna structure generally has various failures, mainly including a foam core material shear failure, a skin damage failure and a buckling instability failure of the hollow carbon fiber square tube, such that the maximum strain & and the Tsai-Wu (TW) coefficient are set as a structural strength limit of the composite skin, and the buckling eigenvalue L is set as a buckling instability failure limit of the hollow carbon fiber square tube in the antenna structure.

In some embodiments, regarding the electrical performance design limit, a structural deformation of the composite phased-array antenna under the in-service status leads to the variations of the antenna unit mounting points, thereby affecting the electrical performance of the composite phased-array antenna, such that an overall electrical performance indicator of the composite phased-array antenna is set as a design limit of the composite phased-array antenna.

In some embodiments, the electrical performance indicators include a pointing angle deviation Δ_{θ}, a gain loss ΔGₘ and a sidelobe level increase ΔG_{α}. It is determined that a design reliability requirement of the structural strength limit and the electrical performance limit is 99.9%, so as to obtain the limit state space based on the design constraint.

In some embodiments, the deterministic design parameter includes caliber and length of a composite rod, and thickness of an antenna unit mounting surface. The random design parameter includes a longitudinal tensile modulus E₁₁, a transverse tensile modulus E₂₂, a shear modulus G and a Poisson's ratio v.

It should be understood that, the design parameter of the composite phased-array antenna includes the deterministic design parameter and the random design parameter. The design parameter directly influences the design constraint and the design object of the antenna structure. The deterministic design parameter and the random design parameter of the antenna structure are extracted based on the structural model. The deterministic design parameter is a design parameter having no uncertainty. A caliber a₁, a length a₂ and a thickness a₃ of the hollow carbon fiber square tube, a thickness a₄ of the middle layer of the antenna unit mounting plate and a thickness a₅ of the carbon fiber composite skin are set as the deterministic design parameter.

In some embodiments, the random design parameter is a design parameter having an uncertainty. Based on an uncertainty of a composite material processing, the longitudinal tensile modulus E₁₁, the transverse tensile modulus E₂₂, the shear modulus G and the Poisson's ratio v are set as the random design parameter, which are configured to characterize mechanical performance of a single-ply carbon fiber fabric and follow the normal distribution. An average and a variance of the random design parameter are respectively determined based on experience and experiment data.

In some embodiments, step (S150) is performed through the following steps.

(S310) A finite element model is established based on the structural model of the composite phased-array antenna, where the structural model is a computer-aided design (CAD) model.

(S320) Structural stiffness and strength analysis is performed based on a load condition of an antenna structure that corresponds to the finite element model under the in-service status to generate a strength analysis result and a stiffness analysis result, where the load condition includes acceleration overload, vibration and structural weight of the composite phased-array antenna characterizing the optimization object.

(S330) A strength indicator is extracted based on the strength analysis result to obtain a relationship between the design parameter, the noise parameter and a strength response.

(S340) A position vector variation of the antenna unit mounting points under the in-service status is extracted based on the stiffness analysis result.

(S350) An overall position vector variation of the antenna unit mounting points is obtained based on the position vector variation in combination with the noise parameter. A relationship, between the design parameter, the noise parameter and an electrical performance constraint including the gain loss, the sidelobe level increase and the pointing angle deviation, is determined.

It should be noted that a relationship, between the design parameter, the noise parameter (such as the thickness of the single carbon fiber fabric T, the manufacturing tolerance of the antenna unit mounting points Arm) and the optimization object (the structural weight of the composite phased-array antenna W), is determined based on the structural model of the composite phased-array antenna.

The finite element model is established based on the structural model of the composite phased-array antenna. The structural stiffness and strength analysis is performed based on the load condition of the antenna structure that corresponds to the finite element model under the in-service status to generate the strength analysis result and the stiffness analysis result. The strength indicator is extracted based on the strength analysis result to obtain the relationship between the design parameter, the noise parameter and the strength response.

The position vector variation of the antenna unit mounting points under the in-service status is extracted based on the stiffness analysis result. The overall position vector variation of the antenna unit mounting points is obtained based on the position vector variation in combination with the noise parameter. The relationship, between the design parameter, the noise parameter and the electrical performance constraint including the gain loss, the sidelobe level increase and the pointing angle deviation, is determined.

In some embodiments, this application has conducted experimental research on the design constraint, the design parameter, the noise parameter, and the optimization object and an optimal value thereof in the design process of the composite phased-array antenna. Relevant data is shown in Table 1.

TABLE 1

| | Average | | Variance | | Probability distribution |
|---|---|---|---|---|---|
| Maximum von Mises stress | 56.8 | MPa | 6.9 | MPa | uncertainty |
| Maximum shear force | 1.8 | MPa | 0.1 | MPa | uncertainty |
| Maximum strain | 1973 | | 67 | | uncertainty |
| Tsai-Wu (TW) coefficient | 0.23 | | 0.02 | | uncertainty |
| Buckling eigenvalue | 0.14 | | 0.01 | | uncertainty |
| Pointing angle deviation | 0.36° | | 0.02° | | uncertainty |
| Gain loss | 1.8 | dB | 0.1 | dB | uncertainty |
| Sidelobe level increase | 2.2 | dB | 0.1 | dB | uncertainty |
| Caliber of hollow carbon fiber square tube | 50 | mm | / | | certainty |
| Length of hollow carbon fiber square tube | 300 | mm | / | | certainty |
| Thickness of hollow carbon fiber square tube | 1.0 | mm | / | | certainty |
| Thickness of middle layer of the antenna | 20 | mm | / | | certainty |
| unit mounting plate | | | | | |
| Thickness of carbon fiber composite skin | 1.0 | mm | / | | certainty |
| Longitudinal tensile modulus | 155 | GPa | 15 | GPa | uncertainty/normal distribution |
| Transverse tensile modulus | 18.5 | GPa | 1.4 | GPa | uncertainty/normal distribution |
| Shear modulus | 8.7 | GPa | 1.1 | GPa | uncertainty/normal distribution |
| Poisson's ratio | 0.28 | | 0.02 | | uncertainty/normal distribution |
| Prepreg ply orientation of carbon fiber | 45° | | 2.3° | | uncertainty/normal distribution |
| Thickness of single-ply carbon fiber fabric | 0.1 | mm | 0.01 | mm | uncertainty/normal distribution |
| Manufacturing tolerance of the antenna | 1.0 | mm | 0.1 | mm | uncertainty/normal distribution |
| unit mounting points | | | | | |
| Structural weight of the composite | 218.5 | Kg | 1.8 | Kg | uncertainty |

phased-array antenna

In some embodiments, the overall electrical performance of the composite phased-array antenna satisfies the following formula:

$$E = {\sum }_{α = 1}^{m} {I}_{α} {e}^{{∅}_{α}} {f}_{α} exp ( α k \hat{r} \cdot ( \overline{{r}_{α}} + Δ \overline{{r}_{α}} ) ) ;$$

where E represents the radiation pattern of the composite phased-array antenna, acting as an indicator for characterizing electrical performance indicator;

$${I}_{α} {e}^{{∅}_{α}}$$

represents an excitation current applied to an antenna unit; f_{α} represents a radiation pattern of the antenna unit;

$$k = \frac{2 π}{{λ}_{0}} ,$$

representing wave constant; λ₀ represents wavelength; \hat{r} represents a unit polarization vector; a̅_̅{̅α̅}̅ represents an initial position vector of a radiation unit; Δr̅_̅{̅α̅}̅ represents an overall position vector variation of a radiation unit; α represents a serial number of the radiation unit; and m represents a total number of the radiation unit.

In some embodiments, the step (S150) is further performed through the following step.

(S410) A sampling is performed on the design parameter and the noise parameter by using a Latin hypercube sampling (LHS) method to select a plurality of sample points and obtain a sampling result.

(S420) A plurality of calculation models for different values of the design parameter and the noise parameter under an in-service status is established based on the sampling result.

(S430) The plurality of calculation models are calculated to obtain a strength response analysis result and an electrical performance response analysis result under the in-service status.

(S440) Based on the strength response analysis result and the electrical performance response analysis result, the design parameter is set as an input, and a corresponding indicator response is set as an output. A deterministic Kriging surrogate model is established by utilizing a Kriging interpolation technique.

In some embodiments, the reliability optimization model satisfies the following formulas:

$$Find : t , {θ}_{x} ;$$

$$Min : W ( t , {θ}_{x} , {θ}_{p} ) ;$$

$$S . t . : Prob [ {M}_{i} ( X , t , p ) \geq 0 ] \geq {R}_{M , i} ;$$

$$Prob [ {E}_{j} ( X , t , p ) \geq 0 ] \geq {R}_{E , j} ;$$

$${t}_{min} \leq t \leq {t}_{max} ; and$$

$${θ}_{x , min} \leq {θ}_{x} \leq {θ}_{x , max} ;$$

where t represents a deterministic design variable; tₘᵢₙ represents a minimum of the deterministic design variable; tₘₐₓ represents a maximum of the deterministic design variable; X represents a random design variable; p represents the noise parameter; θₓ represents an average of the random design variable; θ_{x,min} represents a minimum of the average of the random design variable; θ_{x,max} represents a maximum of the average of the random design variable; θₚ represents an average of the noise parameter; W (t, θₓ, θₚ) represents an object optimization function, and is configured to characterize a structural weight of the composite phased-array antenna; Mᵢ(X, t, p)≥0 represents a probability-constrained function of an i-th strength limit indicator; R_{M,i} represents a threshold of the i-th strength limit indicator; Prob[Mᵢ(X, t, p)≥0]≥R_{M,i} represents a probability of the i-th strength limit indicator; Eⱼ(X, t, p)≥0 represents a probability-constrained function of a j-th electrical performance limit indicator; R_{E,j} represents a threshold of the j-th electrical performance limit indicator; Prob[Eⱼ(X,t,p)≥0]≥R_{E,j} represents a probability of the j-th electrical performance limit indicator; and i and j are each a positive integer.

In some embodiments, step (S170) is performed through the following steps.

(S510) The reliability-based optimization design of the design parameter is divided into a reliability analysis and a deterministic optimization by using a sequential optimization and reliability assessment (SORA) method, followed by an iteration process, where the reliability analysis is performed by a Monte Carlo method.

(S520) Response values corresponding to different design variables in the surrogate model are respectively called during the iteration process. It is determined whether a called response value meets a constraint condition, and a solution meeting the constraint condition is output as the target solution.

In some embodiments, a system for antenna structure optimization design 600 provided herein includes a first determination module 610, a second determination module 620, an extraction module 630, a third determination module 640, a first establishment module 650, a second establishment module 660 and an optimization design module 670.

The first determination module 610 is configured, according to installation requirements, to determine the structure model corresponding to the composite phased-array antenna.

The second determination module 620 is configured to set the structural strength limit and the electrical performance design limit of the composite phased-array antenna as the design constraint, and to determine the design indicator of the design constraint and the reliability requirement thereof, so as to obtain the limit state space based on the design constraint.

The extraction module 630 is configured to extract design parameters of the composite phased-array antenna based on the structural model, where the design parameters include the deterministic design parameter and the random design parameter.

The third determination module 640 is configured to determine the noise parameter of the composite phased-array antenna that follows the random probability distribution, where the noise parameter is related to the design constraint, and includes the prepreg ply orientation, the single-ply prepreg thickness and the variations of the antenna unit mounting points on the antenna unit mounting plate.

The first establishment module 650 is configured to establish the relationship between the design parameter and the optimization object, and the design constraint based on the structural model, to establish the relationship between the noise parameter and the optimization object, and the design constraint based on the structural model, and to establish the surrogate model based on the two relationships, where the optimization object is to minimize the structural weight of the composite phased-array antenna.

The second establishment module 660 is configured, based on the noise parameter and the optimization object, to establish the reliability optimization model with the design parameter as the variable and the limit state space as the optimization constraint.

The optimization design module 670 is configured to perform the reliability-based optimization design on the structure of the composite phased-array antenna to determine a target solution that satisfies the design constraint and characterizes the design parameter.

In some embodiments, the system for antenna structure optimization design 600 provided herein further includes a central processing module 680. The central processing module 680 is configured to send a control instruction to other modules and coordinate actions of other modules. Other modules are configured to be connected to the central processing module 680 and receive the control instruction.

According to the embodiments of the present disclosure, the first determination module 610, the second determination module 620, the extraction module 630, the third determination module 640, the first establishment module 650, the second establishment module 660, the optimization design module 670 and the central processing module 680 can be combined with each other to obtain a combined module for implementation. The first determination module 610, the second determination module 620, the extraction module 630, the third determination module 640, the first establishment module 650, the second establishment module 660, the optimization design module 670 and the central processing module 680 can be each split into a plurality of modules. Some functions of each of the first determination module 610, the second determination module 620, the extraction module 630, the third determination module 640, the first establishment module 650, the second establishment module 660, the optimization design module 670 and the central processing module 680 can be combined with each other and implemented in the combined module.

In some embodiments, the first determination module 610 is configured to specifically implement the following steps.

(S210) The installation requirements of the composite phased-array antenna are obtained, where the installation requirements include the first mounting interface and the external envelope for each of the plurality of standalone modules, and each of the plurality of standalone modules includes the antenna unit array, the power supply unit and the transceiver unit.

(S220) The structural design information of the composite phased-array antenna is determined based on the installation requirements, where the structural design information includes the external dimension, the structural design, the position of the metal embedded part and the second mounting interface.

(S230) The structural model of the composite phased-array antenna is determined based on the structural design information.

In some embodiments, the first establishment module 650 is configured to specifically implement the following steps.

(S310) The finite element model is established based on the structural model of the composite phased-array antenna, where the structural model is the computer-aided design (CAD) model.

(S320) The structural stiffness and strength analysis is performed based on the load condition of the antenna structure that corresponds to the finite element model under the in-service status to generate the strength analysis result and the stiffness analysis result, where the load condition includes the acceleration overload, the vibration and the structural weight of the composite phased-array antenna characterizing the optimization object.

(S330) The strength indicator is extracted based on the strength analysis result to obtain the relationship between the design parameter, the noise parameter and the strength response.

(S340) The position vector variation of the antenna unit mounting points under the in-service status is extracted based on the stiffness analysis result.

(S350) The overall position vector variation of the antenna unit mounting points is obtained based on the position vector variation in combination with the noise parameter. The relationship, between the design parameter, the noise parameter and the electrical performance constraint including the gain loss, the sidelobe level increase and the pointing angle deviation, is determined.

In some embodiments, the first establishment module 650 is further configured to specifically implement the following steps.

(S410) The sampling is performed on the design parameter and the noise parameter by using the Latin hypercube sampling (LHS) method to select the plurality of sampling points and obtain the sampling result.

(S420) The plurality of calculation models for different values of the design parameter and the noise parameter are established based on the sampling result.

(S430) The plurality of calculation models are calculated to obtain the strength response analysis result and the electrical performance response analysis result under the in-service status.

(S440) Based on the strength response analysis result and the electrical performance response analysis result, the design parameter is set as the input, and the corresponding indicator response is set as the output. The deterministic Kriging surrogate model is established by utilizing the Kriging interpolation technique.

In some embodiments, the optimization design module 670 is configured to specifically implement the following steps.

(S510) The reliability-based optimization design of the design parameter is divided into the reliability analysis and the deterministic optimization by using the sequential optimization and reliability assessment (SORA) method, followed by an iteration process, where the reliability analysis is performed by the Monte Carlo method.

(S520) The response values corresponding to different design variables in the surrogate model are respectively called during the iteration process. It is determined whether the called response value meets the constraint condition, and the solution meeting the constraint condition is output as the target solution.

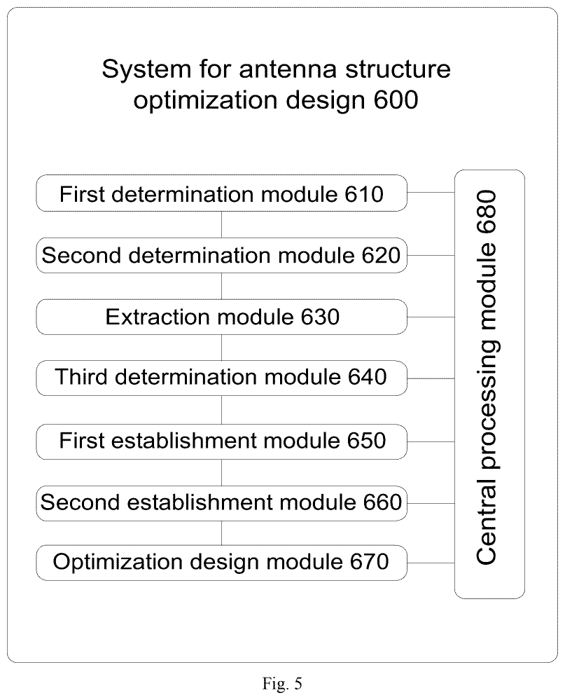

Referring to FIG. 5, the aforementioned modules in the system for antenna structure optimization design are configured to implement the method for antenna structure optimization design and enable the technical effects of the method provided herein. For the sake of brevity, it will not be elaborated herein.

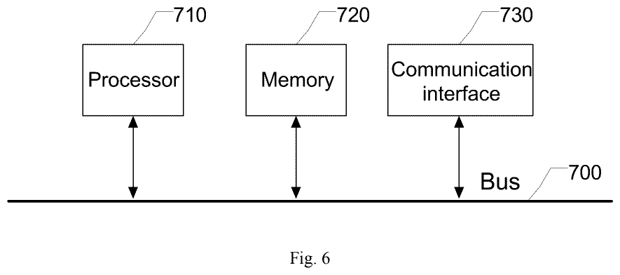

In some embodiments, the present disclosure provides an electronic device. The electronic device is structurally shown in FIG. 6. The electronical device includes a processor 710 and a memory 720 configured for storing a computer program instruction.

In some embodiments, the processor 710 is a center processing unit (CPU) or an application specific integrated circuit (ASIC). The processor 710 is also configured as a plurality of integrated circuits to implement the embodiments of the present disclosure.

In some embodiments, the memory 720 is a mass storage device configured for storing data and instructions. Taking an example for illustrating rather than limiting, the memory 720 is selected from the group consisting of a hard disk device (HDD), a soft disk device (SDD), a flash memory, a compact disc, an magnetooptical disk, a magnetic tape, a universal serial bus (USB) and a combination thereof. Under appropriate conditions, the memory 720 includes a removable or a non-removable (or fixed) medium. Under appropriate conditions, the memory 720 is arranged inside or outside a disaster recovery equipment of an integrated gateway.

In a specific embodiment, the memory 720 is a non-volatile solid-state memory.

In some embodiments, the memory 720 is selected from the group consisting of a read-only memory (ROM), a random access memory (RAM), a disk storage medium device, an optical storage medium device, a flash memory device and a physical/tangible memory storage device (e.g., an electrical memory storage device and an optical memory storage device). Consequently, the memory 720 typically includes at least one tangible (non-transient) computer-readable storage medium (e.g., a memory device) encoded with a software including computer-executable instructions. When the software is executed (e.g., by one or more processors), the software is configured to perform the steps described in the embodiments.

In some embodiments, the pressor 710 is configured to read and execute the computer program instruction stored in the memory 720, so as to implement the methods for antenna structure optimization design in the embodiments of the present disclosure.

In some embodiments, the electronic device includes a communication interface 730 and a bus 700. As shown in FIG. 6, the processor 710, the memory 720, and the communication interface 730 are connected via the bus 700 to enable a communication with each other.

The communication interface 730 is configured to facilitate communication between various modules, apparatuses, units, and/or devices in the embodiments of the present disclosure. The bus 700 is selected from the group consisting of a hardware, a software and a combination thereof, and is configured to couple components of an online data traffic billing device to each other. The examples below are not intended to limit the bus 700. The bus 700 is selected from the group consisting of an accelerated graphics port (AGP) or another graphics bus, an enhanced industry standard architecture (EISA) bus, a front-side bus (FSB), a hyper transport (HT) interconnect, an industry standard architecture (ISA) bus, an InfiniBand interconnect, a low pin count (LPC) bus, a memory bus, micro channel architecture (MCA) bus, a peripheral component interconnect (PCI) bus, a PCI-Express (PCI-X) bus, a serial advanced technology attachment (SATA) bus, a video electronics standards association local bus (VLB) and a combination thereof. The bus 700 includes at least one bus based on practical conditions. Although the embodiments of the present disclosure describe and show a specific bus, the present disclosure considers any appropriate bus or an interconnect.

It should be noted that the specific configurations and treatments described above and shown in the figures are not intended to limit this application. For the sake of brevity, not all possible implementation methods have been described herein. In the above embodiments, a plurality of steps described and shown herein are merely illustrative. Nevertheless, the plurality of steps are not intended to limit the process method of the present disclosure. For those skilled in the art, various changes, modifications and additions can be made after understanding the spirit of the present disclosure, or a sequence of the plurality of steps can be changed.

The functional modules shown in the above structural block charts are each implemented as a hardware, a software, a firmware or a combination thereof. When as the hardware, it is selected from the group consisting of an electronic circuit, an application specific integrated circuit (ASIC), an appropriate firmware, a plug-in, a function card and a combination thereof. When as the software, an element of the present disclosure is a program or a code segment needed in executing a desired task. The program and the code segment are stored in a machine-readable medium, or transmitted over a transmission media or a communication link through a data signal carried in a carrier. The machine-readable medium includes any medium capable of storing or transmitting information. The machine-readable medium is selected from the group consisting of an electronic circuit, a semiconductor memory device, a read-only memory (ROM), a flash memory, an erasable read-only memory ROM (EROM), a floppy disk, a compact disc read-only memory (CD-ROM), an optical disc, a hard disk, an optical fiber medium, a radio frequency (RF) link and a combination thereof. The code segment can be downloaded by a computer network such as Internet and Intranet.

It should be noted that, the illustrative embodiments provided herein describe some methods or systems based on a series of steps or devices. Nevertheless, this application is not intended to limit the sequence of the above steps. In other words, the steps are performed according to a sequence described in the embodiments or a sequence different from it, or a plurality of the above steps are performed simultaneously.

All aspects of the present disclosure have been described with reference to the methods, the devices (systems) and the flow charts and/or block charts of computer program products in the embodiments of the present disclosure. It should be understood that a combination between each block of the flow charts and/or the block charts and each block of the flow charts and/or block charts can be implemented by a computer program instruction. The computer program instruction can be provided for processors of a general-purpose computer, a special-purpose computer, or other programmable data processing devices to generate a machine, such that the computer program instruction executed by the processor of a computer or other programmable data processing devices enable an implementation of a function/action specified in one or more blocks of the flow charts and/or block charts. The processor is selected from the group consisting of a general-purpose processor, a specific-purpose processor, a special application processor and a field-programmable logic circuit. It should be also understood that the combination between each block of the flow charts and/or block charts and each block of the flow charts and/or block charts can be implemented by a specific-purpose hardware that performs a specified function or action, or by a combination of the specific-purpose hardware and the computer instruction.

Compared to the prior art, the present disclosure has the following beneficial effects.

The method provided herein considers the uncertainties of the structural dimensions and mechanical properties based on the stiffness, strength, and electrical performance of the antenna structure under the in-service status, enabling the rapid weight optimization of the antenna structure. Compared to the conventional design method based on safety factors, this application enables a more thorough lightweight design for the phased-array antenna structure, while ensuring the high reliability that the stiffness, strength, and electrical performance indicators satisfy the requirements.

This application provides a convenient, fast and effective method for the structural optimization design of the composite phased-array antenna, significantly shortening the design iteration cycle for the composite phased-array antenna and substantially reducing development costs.

The above embodiments are merely illustrative, and are not intended to limit this present disclosure. It should be understood that, although the present disclosure has been described detailly with reference to the aforementioned embodiments, various modifications and equal replacements made by those of ordinary skill in the art without departing from the spirit of the present disclosure shall fall within the scope of the present disclosure defined by the appended claims.

What is claimed is:

1. A method for antenna structure optimization design, comprising:
(S1) according to installation requirements, determining a structural model corresponding to a composite phased-array antenna;
(S2) setting a structural strength limit and an electrical performance design limit of the composite phased-array antenna as a design constraint; and determining a design indicator of the design constraint and a reliability requirement of the design constraint, so as to obtain a limit state space based on the design constraint;
(S3) extracting design parameters of the composite phased-array antenna from the structural model, wherein the design parameters comprise a deterministic design parameter and a random design parameter;
(S4) determining a noise parameter of the composite phased-array antenna that follows a random probability distribution, wherein the noise parameter is related to the design constraint, and comprises a prepreg ply orientation, a single-ply prepreg thickness and variations of antenna unit mounting points on an antenna unit mounting plate;
(S5) establishing a relationship between the design parameters and an optimization object, and the design constraint based on the structural model; establishing a relationship between the noise parameter and the optimization object, and the design constraint based on the structural model; and establishing a surrogate model based on the two relationships; wherein the optimization object is to minimize a structural weight of the composite phased-array antenna;
(S6) based on the noise parameter and the optimization object, establishing a reliability optimization model with the design parameter as a variable and the limit state space as an optimization constraint; and
(S7) performing reliability-based optimization design on a structure of the composite phased-array antenna to determine a target solution that satisfies the design constraint and characterizes the design parameter;
wherein the structure of the composite phased-array antenna comprises the antenna unit mounting plate and a truss structure; the antenna unit mounting plate is provided with a plurality of antenna unit mounting holes in an array distribution; the plurality of antenna unit mounting holes are configured to mount an antenna unit array; the truss structure is formed by joining a plurality of hollow carbon fiber square tubes; and a metal embedded part is provided at a joint between two adjacent tubes of the plurality of hollow carbon fiber square tubes; and
the design indicator of the structural strength limit comprises a maximum von Mises stress, a maximum shear force of a composite core material, a maximum strain of a composite skin, a Tsai-Wu coefficient and a buckling eigenvalue corresponding to rod or panel buckling failure; the electrical performance design limit is configured to characterize an overall electrical performance of the composite phased-array antenna; and the design indicator corresponding to the electrical performance design limit comprises a radiation pattern, a pointing angle deviation, a gain loss and a sidelobe level increase.

2. The method of claim 1, wherein step (S1) is performed through steps of:
obtaining the installation requirements of the composite phased-array antenna, wherein the installation requirements comprise a first mounting interface and an external envelope for each of a plurality of standalone modules, and each of the plurality of standalone modules comprises the antenna unit array, a power supply unit and a transceiver unit;
determining structural design information of the composite phased-array antenna based on the installation requirements, wherein the structural design information comprises external dimension, composite structural design, position of the metal embedded part and a second mounting interface; and
determining the structural model of the composite phased-array antenna based on the structural design information.

3. The method of claim 1, wherein the deterministic design parameter comprises caliber and length of a composite rod, and thickness of an antenna unit mounting surface;
the random design parameter comprises a longitudinal tensile modulus E₁₁, a transverse tensile modulus E₂₂, a shear modulus G and a Poisson's ratio v, which are configured to characterize mechanical performance of a single-ply carbon fiber fabric;
the prepreg ply orientation and the single-ply prepreg thickness are correlated with stiffness and strength of the composite phased-array antenna; and
the variations of the antenna unit mounting points are correlated with the electrical performance of the composite phased-array antenna.

4. The method of claim 1, wherein step (S5) comprises:
establishing a finite element model based on the structural model of the composite phased-array antenna, wherein the structural model is a computer-aided design (CAD) model;
performing structural stiffness and strength analysis based on a load condition of an antenna structure that corresponds to the finite element model under an in-service status to generate a strength analysis result and a stiffness analysis result, wherein the load condition comprises acceleration overload, vibration and structural weight of the composite phased-array antenna characterizing the optimization object;
extracting a strength indicator based on the strength analysis result to obtain a relationship between the design parameter, the noise parameter and a strength response;
extracting a position vector variation of the antenna unit mounting points under the in-service status based on the stiffness analysis result;
obtaining an overall position vector variation of the antenna unit mounting points based on the position vector variation in combination with the noise parameter; and
determining a relationship between the design parameter, the noise parameter and an electrical performance constraint comprising the gain loss, the sidelobe level increase and the pointing angle deviation;
wherein the overall electrical performance of the composite phased-array antenna satisfies the following formula:
$$E = {\sum }_{α = 1}^{m} {I}_{α} {e}^{{∅}_{α}} {f}_{α} exp ( α k \hat{r} \cdot ( \overline{{r}_{α}} + Δ \overline{{r}_{α}} ) ) ;$$
wherein E represents the radiation pattern of the composite phased-array antenna, acting as an indicator for characterizing electrical performance indicator;
$${I}_{α} {e}^{{∅}_{α}}$$
represents an excitation current applied to an antenna unit; f_{α} represents a radiation pattern of the antenna unit;
$$k = \frac{2 π}{{λ}_{0}} ,$$
representing wave constant; λ₀ represents wavelength; \hat{r} represents a unit polarization vector; \hat{r}_{α} represents an initial position vector of a radiation unit; Δ\hat{r}_{α} represents an overall position vector variation of the radiation unit; α represents a serial number of the radiation unit; and m represents a total number of the radiation unit.

5. The method of claim 4, wherein the step (S5) further comprises:
performing sampling on the design parameter and the noise parameter by using a Latin hypercube sampling (LHS) method to select a plurality of sample points and obtain a sampling result;
establishing a plurality of calculation models for different values of the design parameter and the noise parameter under an in-service status based on the sampling result;
calculating the plurality of calculation models to obtain a strength response analysis result and an electrical performance response analysis result under the in-service status; and
based on the strength response analysis result and the electrical performance response analysis result, setting the design parameter as an input and a corresponding indicator response as an output; and establishing a deterministic Kriging surrogate model by utilizing a Kriging interpolation technique.

6. The method of claim 1, wherein the reliability optimization model satisfies the following formulas:
$$Find : t , {θ}_{x} ;$$
$$Min : W ( t , {θ}_{x} , {θ}_{p} ) ;$$
$$S . t . : Prob [ {M}_{i} ( X , t , p ) \geq 0 ] \geq {R}_{M , i} ;$$
$$Prob [ {E}_{j} ( X , t , p ) \geq 0 ] \geq {R}_{E , j} ;$$
$${t}_{min} \leq t \leq {t}_{max} ; and$$
$${θ}_{x , min} \leq {θ}_{x} \leq {θ}_{x , max} ;$$
wherein t represents a deterministic design variable; tₘᵢₙ represents a minimum of the deterministic design variable; tₘₐₓ represents a maximum of the deterministic design variable; X represents a random design variable; p represents the noise parameter; θₓ represents an average of the random design variable; θ_{x,min} represents a minimum of the average of the random design variable; θ_{x,max} represents a maximum of the average of the random design variable; θₚ represents an average of the noise parameter; and W (t, θₓ, θₚ) represents an object optimization function, and is configured to characterize a structural weight of the composite phased-array antenna;
Mᵢ(X,t,p)≥0 represents a probability-constrained function of an i-th strength limit indicator; R_{M,i} represents a threshold of the i-th strength limit indicator; Prob [Mᵢ(X,t,p)≥0]R_{M,i} represents a probability of the i-th strength limit indicator; and
Eⱼ(X,t,p)≥0 represents a probability-constrained function of a j-th electrical performance limit indicator; R_{E,j} represents a threshold of the j-th electrical performance limit indicator; Prob [Eⱼ(X,t,p)≥0]≥R_{E,j} represents a probability of the j-th electrical performance limit indicator; and i and j are each a positive integer.

7. The method of claim 1, wherein step (S7) is performed through steps of:
dividing the reliability-based optimization design of the design parameter into a reliability analysis and a deterministic optimization by using a sequential optimization and reliability assessment (SORA) method, followed by an iteration process, wherein the reliability analysis is performed by a Monte Carlo method; and
respectively calling response values corresponding to different design variables in the surrogate model during the iteration process; and
determining whether a called response value meets a constraint condition, and outputting a solution meeting the constraint condition as the target solution.

8. A system for antenna structure optimization design, comprising:
a first determination module;
a second determination module;
an extraction module;
a third determination module;
a first establishment module;
a second establishment module; and
an optimization design module;
wherein the first determination module is configured, according to installation requirements, to determine a structure model corresponding to a composite phased-array antenna;
the second determination module is configured to set a structural strength limit and an electrical performance design limit of the composite phased-array antenna as a design constraint, and to determine a design indicator of the design constraint and a reliability requirement thereof, so as to obtain a limit state space based on the design constraint;
the extraction module is configured to extract design parameters of the composite phased-array antenna based on a structural model, wherein the design parameters comprise a deterministic design parameter and a random design parameter;
the third determination module is configured to determine a noise parameter of the composite phased-array antenna that follows a random probability distribution, wherein the noise parameter is related to the design constraint, and comprises a prepreg ply orientation, a single-ply prepreg thickness and variations of antenna unit mounting points on an antenna unit mounting plate;
the first establishment module is configured to establish a relationship between the design parameters and an optimization object, and the design constraint based on the structural model, to establish a relationship between the noise parameter and the optimization object, and the design constraint based on the structural model, and to establish a surrogate model based on the two relationships, wherein the optimization object is to minimize a structural weight of the composite phased-array antenna;
the second establishment module is configured, based on the noise parameter and the optimization object, to establish a reliability optimization model with the design parameter as a variable and the limit state space as an optimization constraint; and
the optimization design module is configured to perform reliability-based optimization design on a structure of the composite phased-array antenna to determine a target solution that satisfies the design constraint and characterizes the design parameter;
wherein the structure of the composite phased-array antenna comprises the antenna unit mounting plate and a truss structure; the antenna unit mounting plate is provided with a plurality of antenna unit mounting holes in an array distribution; the plurality of antenna unit mounting holes are configured to mount an antenna unit array; the truss structure is formed by joining a plurality of hollow carbon fiber square tubes; and a metal embedded part is provided at a joint between two adjacent tubes of the plurality of hollow carbon fiber square tubes; and
the design indicator of the structural strength limit comprises a maximum von Mises stress, a maximum shear force of a composite core material, a maximum strain of a composite skin, a Tsai-Wu coefficient and a buckling eigenvalue corresponding to rod or panel buckling failure; the electrical performance design limit is configured to characterize an overall electrical performance of the composite phased-array antenna; and the design indicator corresponding to the electrical performance design limit comprises a radiation pattern, a pointing angle deviation, a gain loss and a sidelobe level increase.

9. An electronic device, comprising:
a processor;
a memory; and
a program stored on the memory and executed by the processor;
wherein the program is configured, when executed by the processor, to cause the processor to implement the method of claim 1.
